(19) United States
(12) Patent Application Publication
(10) Pub. No.: US 2021/0190822 A1
(43) Pub. Date: Jun. 24, 2021

(54) MULTI-LAYER MEMS SPRING PIN

(71) Applicant: OKINS ELECTRONICS CO., LTD, Uiwang-si (KR)

(72) Inventors: Jin Kook JUN, Gunpo-si (KR); Sang Hoon CHA, Hwaseong-si (KR); Chang Mo JEONG, Gwangmyeong-si (KR)

(21) Appl. No.: 17/193,449

(22) Filed: Mar. 5, 2021

Related U.S. Application Data
(63) Continuation of application No. PCT/KR2020/004957, filed on Apr. 13, 2020.

(30) Foreign Application Priority Data
Apr. 15, 2019 (KR) 10-2019-0043692
Apr. 10, 2020 (KR) 10-2020-0043942

(51) Int. Cl. G01R 1/067

(52) U.S. Cl. CPC G01R 1/06722; G01R 1/0675

(57) ABSTRACT

A three-layer micro electro mechanical system (MEMS) spring pin includes a lower-layer spring pin in which a lower-layer wave is disposed between and connected to a lower-layer top plunger and a lower-layer bottom plunger, an upper-layer spring pin in which an upper-layer wave is disposed between and connected to an upper-layer top plunger and an upper-layer bottom plunger, a middle-layer top tip interposed between the upper-layer top plunger and the lower-layer top plunger, and a middle-layer bottom tip interposed between the upper-layer bottom plunger and the lower-layer bottom plunger. According to the above-described structure, effects are expected in which bending is prevented, a stroke is stabilized due to the multi-layer spring, and contact characteristics are enhanced due to the multi-layer plunger.

### TECHNICAL FIELD

The present invention relates to a multi-layer spring pin using a micro electro mechanical system (MEMS), and more specifically, to a MEMS spring pin in which MEMS one-layer spring pins, each of which is easily bent, are stacked in multiple layers to prevent bending and simultaneously enhance a vertical stroke through a multi-spring region and a length and shape of a connection tip of each layer is allowed to be different through a multi-plunger region to enhance contact characteristics when a semiconductor device is electrically tested.

### BACKGROUND ART

Generally, a test apparatus for electrically testing a semiconductor device is formed to include a spring pin. That is, when an end portion of the spring pin comes into contact with a test target, that is, a ball terminal provided on the semiconductor device, an electrical signal is transmitted to a printed circuit board (PCB) and electrical characteristics of the test target may be detected.

Conventionally, when the above-described spring pin is manufactured, for example, a copper plate is mechanically or physically machined to manufacture the spring pin. Such a machining method has problems of lowering manufacturing productivity of the spring pin and increasing a manufacturing cost.

Meanwhile, when the spring pin comes into contact with the test target, a mechanical impact is transferred to the spring pin and a test is repeated several tens of thousands of times so that a spring is elastically deformed due to the impacts. When elasticity of the spring is degraded, a restoration force is lowered, contact characteristics are degraded, and thus test reliability is lowered. Finally, a test pin should be replaced.

When the elasticity of the spring in the spring pin is not maintained, a lifetime of the spring pin is shortened, a replacement cycle is shortened, and a cost is increased thereby.

### PRIOR ART

### [Patent Document]

Korean Patent Publication No. 10-2017-0055618

### DISCLOSURE

### Technical Problem

The present invention is directed to providing a multi-layer micro electro mechanical system (MEMS) spring pin in a multi-layer strip type using a MEMS process.

The present invention is also directed to providing a multi-layer MEMS spring pin in which springs are stacked in multiple stages to prevent bending and to maintain contact characteristics thereof.

The present invention is also directed to providing a multi-layer MEMS spring pin in which plungers are stacked in multiple layers to vary a length and a shape of a line tip.

The present invention is also directed to providing a multi-layer MEMS spring pin allowing a plurality of different signals to be processed using one pin.

### Technical Solution

One aspect of the present invention provides a multi-layer micro electro mechanical system (MEMS) spring pin including a lower-layer spring pin in which a lower-layer wave is disposed between and connected to a lower-layer top plunger and a lower-layer bottom plunger, an upper-layer spring pin in which an upper-layer wave is disposed between and connected to an upper-layer top plunger and an upper-layer bottom plunger, a middle-layer top tip interposed between the upper-layer top plunger and the lower-layer top plunger, and a middle-layer bottom tip interposed between the upper-layer bottom plunger and the lower-layer bottom plunger.

The lower-layer top plunger may include a lower-layer top body and a lower-layer top tip, and the upper-layer top plunger may include an upper-layer top body and an upper-layer top tip.

The middle-layer top tip may extend upward further than the upper-layer and lower-layer top tips.

The upper-layer and lower-layer top tips may extend upward further than the middle-layer top tip.

The multi-layer MEMS spring pin may further include one or more middle-layer interposers interposed between the upper-layer wave and the lower-layer wave.

The middle-layer interposer is bonded to one of the upper-layer and lower-layer waves.

A protrusion portion of the lower-layer wave may correspond to a groove portion of the upper-layer wave, and a groove portion of the lower-layer wave may correspond to a protrusion portion of the upper-layer wave.

Another aspect of the present invention provides a MEMS spring pin including a lower-layer spring pin in which a lower-layer wave is disposed between and connected to a lower-layer top plunger and a lower-layer bottom plunger, an upper-layer spring pin in which an upper-layer wave is disposed between and connected to an upper-layer top plunger and an upper-layer bottom plunger, a first insulating layer interposed between the upper-layer top plunger and the lower-layer top plunger, and a second insulating layer interposed between the upper-layer bottom plunger and the lower-layer bottom plunger.

The first insulating layer does not protrude upward from the upper-layer top plunger and the lower-layer top plunger, and the second insulating layer does not protrude downward from the upper-layer bottom plunger and the lower-layer bottom plunger.

The multi-layer MEMS spring pin may further include an intermediate insulating layer positioned between the lower-layer wave of the lower-layer spring pin and the upper-layer wave of the upper-layer spring pin.

The intermediate insulating layer may be provided as two or more intermediate insulating layers, and each of the intermediate insulating layers may be alternately attached to the lower-layer wave or the upper-layer wave.

The lower-layer top plunger may include a lower-layer top body and a lower-layer top tip, and the upper-layer top plunger may include an upper-layer top body and an upper-layer top tip.

### Advantageous Effects

As described above, the following effects can be expected according to a configuration of the present invention.

First, when a spring pin is manufactured, since springs are stacked in a multi-layer such as a two-layer or three-layer, a vertical stroke is stabilized first and elastic forces of layers act complexly, and thus an effect is expected in which contact characteristics can be maintained even when the spring pin is used for a long time or an excessive load is applied to the spring pin.

Second, since a micro electro mechanical system (MEMS) or etch process is used, an effect is expected in which mass production is allowed through sequential processes, a defect rate can be significantly reduced, and thus a process yield can be significantly increased.

Third, when plungers are stacked in a multi-layer, an effect is expected in which contact characteristics may vary by changing a length or a shape of a front end of each layer.

In addition, in another embodiment of the present invention, since a structure for supplying a plurality of signals using one pin is provided, effects are expected in which an application range can be increased and test reliability can be improved.

### DESCRIPTION OF DRAWINGS

FIGS. 1 to 4 are a front perspective view, a bottom perspective view, a front view, and a side view illustrating a structure of a two-layer micro electro mechanical system (MEMS) spring pin according to one embodiment of the present invention.

FIG. 5 is a perspective view for describing a method of manufacturing a two-layer.

FIGS. 6 to 8 are a perspective view, a front view, and a side view illustrating a structure of a three-layer MEMS spring pin according to another embodiment of the present invention.

FIGS. 9 and 10 are side views illustrating various structures of three-layer MEMS spring pins including middle-layer interposers.

FIG. 11 is a partially enlarged view illustrating a structure of a three-layer MEMS spring pin according to still another embodiment of the present invention.

FIG. 12 is a perspective view illustrating a MEMS spring pin according to another embodiment of the present invention.

FIG. 13 is a side view of FIG. 12.

FIGS. 14 and 15 are side views illustrating MEMS spring pins including intermediate insulating layers according to another embodiment of the present invention.

### REFERENCE NUMERALS

100: TWO-LAYER MICRO ELECTRO MECHANICAL SYSTEM (MEMS) SPRING PIN
110: TOP PLUNGER
120: TWO-LAYER ELASTIC BODY
120A: LOWER-LAYER WAVE
120B: UPPER-LAYER WAVE
130: BOTTOM PLUNGER
200: THREE-LAYER MEMS SPRING PIN
210: LOWER-LAYER SPRING PIN
220: UPPER-LAYER SPRING PIN
241: FIRST INSULATING LAYER
242: SECOND INSULATING LAYER
243, 244, 245: INTERMEDIATE INSULATING LAYER

### MODES OF THE INVENTION

Advantages and features of the present invention and methods of achieving the same will be clearly understood with reference to the following embodiments and the accompanying drawings. However, the present invention is not limited to the embodiments to be disclosed below and may be implemented in various different forms. The embodiments are provided in order to fully explain the present invention and fully explain the scope of the present invention for those skilled in the art. The scope of the present invention is only defined by the appended claims. In the drawings, the sizes of and relative sizes between layers and regions are exaggerated for clarity. Like reference numerals refer to like elements throughout the specification.

The embodiment described in this specification will be described with reference to exemplary and schematic plan and cross-sectional views. Accordingly, forms of the exemplary views may be changed due to a manufacturing technology and/or a tolerance thereof. Accordingly, the embodiments of the present invention are not limited to illustrated specific forms and include changes in form manufactured through manufacturing processes. Accordingly, regions illustrated in the drawings have schematic properties, and the shapes thereof are to illustrate specific forms of the regions of elements illustrated in the drawings but not to limit a specific scope the present invention.

A multi-layer micro electro mechanical system (MEMS) spring pin will be described to be used in a final test socket for the sake of convenience in the description but may also be used in a burn-in test socket.

The test socket is disposed between a semiconductor device and a test apparatus to electrically connect a connection terminal (for example, conductive ball) of the semiconductor device which is a test target and a connection terminal (for example, contact pad) of the test apparatus when a semiconductor device such as a semiconductor IC device, for example, a package IC and a multi-chip module (MCM), and a wafer in which an IC is formed is tested.

Although not illustrated in the drawings, a spring pin of the test socket electrically connects a conductive ball of an external device, for example, the semiconductor device and a contact pad of the test apparatus so that the test apparatus electrically tests the semiconductor device through the spring pin disposed therebetween.

Particularly, since a single-layer spring pin is formed to have a plate form which is substantially a two-dimensional strip form and whose thickness is much less than a width of a general pogo pin, the single-layer spring pin has advantages in that the single-layer spring pin is allowed to be sequentially manufactured and a precise machining is secured using a MEMS process.

Hereinafter, exemplary embodiments of a multi-layer spring pin having the above-described configuration and formed using a MEMS according to the present invention will be described in detail with reference to the accompanying drawings.

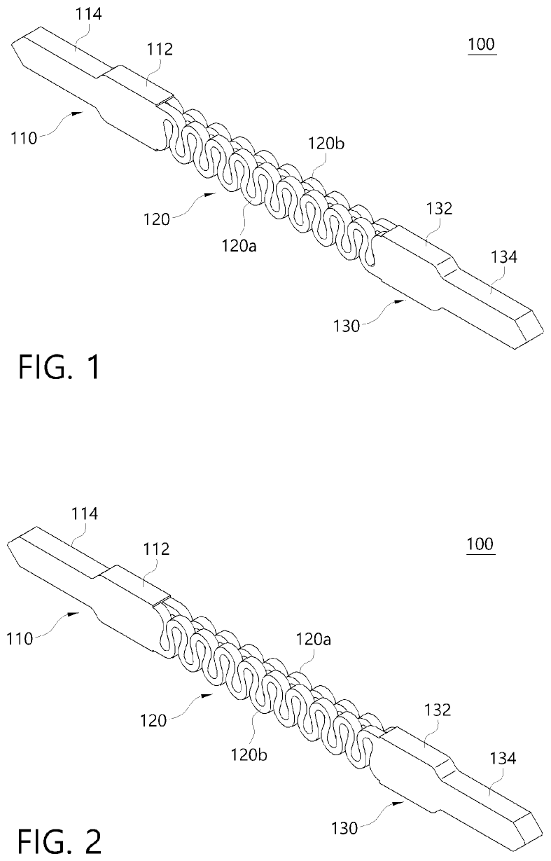

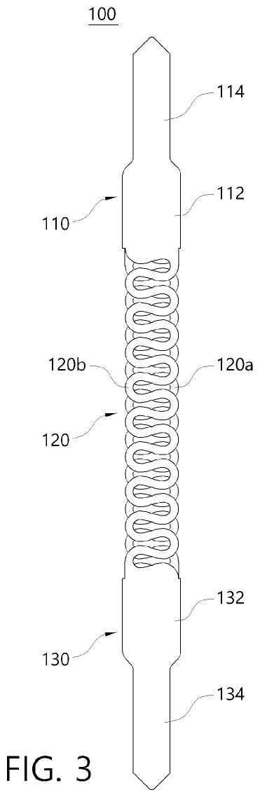

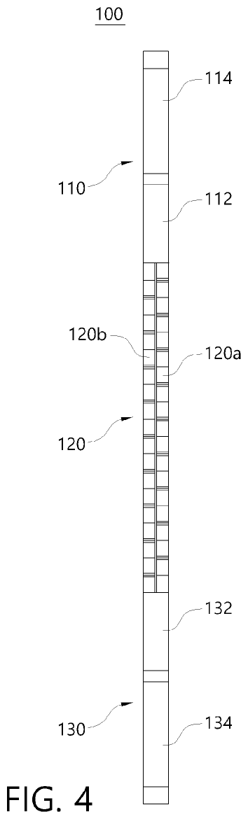

Referring to FIGS. 1 to 4, a two-layer MEMS spring pin 100 includes a top plunger 110 configured to come into contact with a conductive ball or contact pad, an elastic body 120 integrally extending from the top plunger 110 and stacked as a two-layer, and a bottom plunger 130 configured to come into contact with a contact pad or conductive ball and integrally extending from the elastic body 120.

The spring pin 100 of the present invention has a bidirectional symmetrical type in which the top plunger 110 and the bottom plunger 130 which are disposed at both ends thereof are integrally connected through the elastic body but does not need to be necessarily symmetrical, and the top plunger 110 and the bottom plunger 130 may be provided as an asymmetrical type.

The top plunger 110 includes a top body 112 and a top tip 114 extending from the top body 112 and having a diameter less than a diameter of the top body 112. The bottom plunger 130 includes a bottom body 132 and a bottom tip 134 extending from the bottom body 132 and having a diameter less than a diameter of the bottom body 132.

In the top plunger 110, an upper-layer top plunger and a lower-layer top plunger may be bonded through an adhesive or a coupling method. Alternatively, the upper-layer top plunger and the lower-layer top plunger may be integrally provided. In any case, the top plunger 110 operates integrally. The bottom plunger 130 operates in the same manner as the top plunger 110.

Accordingly, the elastic body 120 extends directly from the body 112. The body 112 may be installed in a test socket in a state in which the body 112 is directly supported by the test socket or mounted on a barrel.

The two-layer elastic body 120 includes a lower-layer wave 120a and an upper-layer wave 120b. The waves 120a and 120b are connected through only the top and bottom plungers 110 and 130 and do not interfere with each other. For example, the upper-layer and lower-layer waves 120b and 120a are vertically separated by a distance, or even when the upper-layer and lower-layer waves 120b and 120a are not separated, the upper-layer and lower-layer waves 120b and 120a are not connected and have an independent structure.

In the lower-layer wave 120a, protrusion portions and groove portions are repeated from one side based on a central line thereof, and in the upper-layer wave 120b, protrusion portions and groove portions are repeated from the other side.

Accordingly, on the basis of one side based on the central line, the protrusion portion of the lower-layer wave 120a corresponds to and intersects with the groove portion of the upper-layer wave 120b, and the groove portion of the lower-layer wave 120a corresponds to and intersects with the protrusion portion of the upper-layer wave 120b. In addition, the protrusion portions and the groove portions of the lower-layer wave 120a are symmetrical with the protrusion portions and the groove portions of the upper-layer wave 120b on the basis of the central line. The groove portion of the lower-layer wave 120a overlaps the protrusion portion of the upper-layer wave 120b, and the protrusion portion of the lower-layer wave 120a overlaps the groove portion of the upper-layer wave 120b so that the protrusion portions and the groove portions of the lower-layer wave 120a are symmetrical with the protrusion portions and the groove portions of the upper-layer wave 120b on the basis of the central line.

A one-layer elastic body has an asymmetrical structure with respect to a central line because of an uneven structure thereof, but when two-layer elastic bodies overlap to intersect with each other, the symmetrical structure is finally formed.

In a line spring structure, an impact of a vertically applied load is easily absorbed in a longitudinal direction in which irregularities are formed in a zigzag shape, but the spring structure is very weak against an impact of a laterally applied load when compared to a coil spring structure. Accordingly, when the line spring structure is formed into a two-layer structure, bending due to a lateral load may be prevented.

In addition, since a one-layer elastic body has only one elastic modulus, the one-layer elastic body has simple contact characteristics and has a fatal disadvantage of degradation of the contact characteristics when used for a long time. However, in the two-layer elastic body, since a plurality of springs having various elastic forces have a complex elasticity, the contact characteristics of the two-layer elastic body can be maintained against repeated use or an excessive load due to a strong stroke thereof.

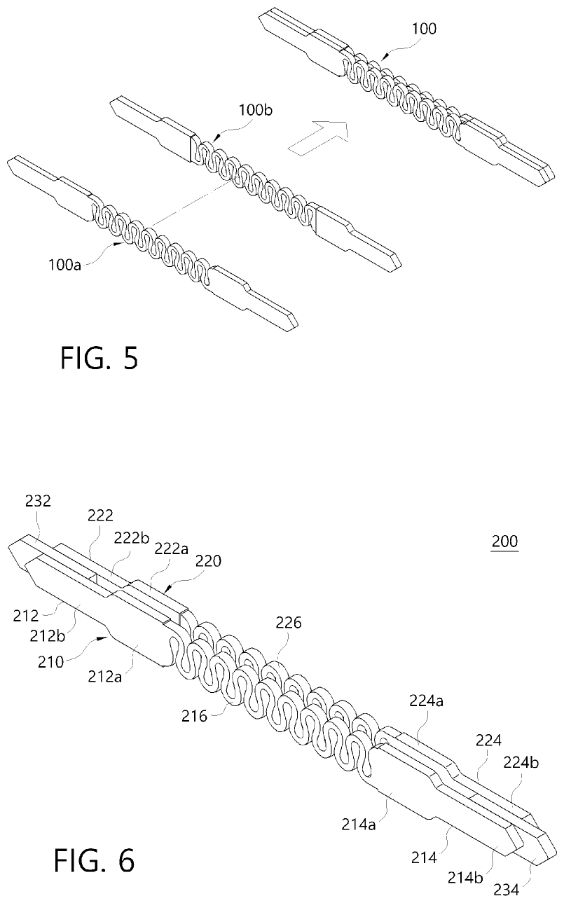

Each of the layers of the present invention may be provided in a strip form through a MEMS process, a press process, or an etch process. As illustrated in FIG. 5, the layers 100a and 110b may be prepared in advance and finally coupled. Alternatively, the lower-layer layer 100a may be formed through deposition and etch processes, and subsequently, the upper-layer layer 100b may be formed on the lower-layer layer 100a through deposition and etch processes.

Hereinafter, a three-layer MEMS spring pin will be described with reference to the accompanying drawings.

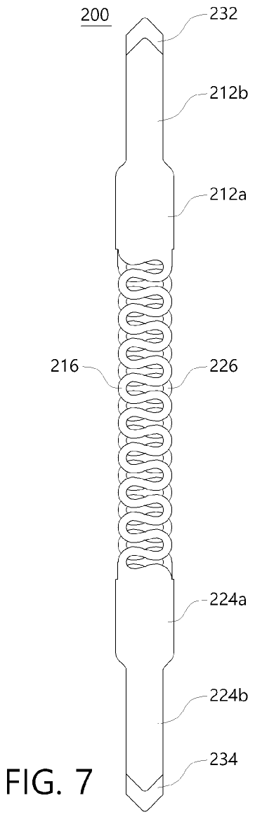

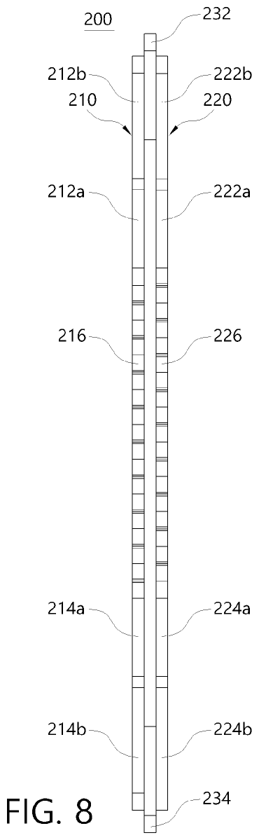

Referring to FIGS. 6 to 8, a three-layer MEMS spring pin 200 includes a lower-layer spring pin 210 in which a lower-layer wave 216 is disposed between and connected to a lower-layer top plunger 212 and a lower-layer bottom plunger 214, an upper-layer spring pin 220 in which an upper-layer wave 226 is disposed between and connected to an upper-layer top plunger 222 and a upper-layer bottom plunger 224, a middle-layer top tip 232 interposed between the upper-layer top plunger 222 and the lower-layer top plunger 212, and a middle-layer bottom tip 234 interposed between the upper-layer bottom plunger 224 and the lower-layer bottom plunger 214.

The lower-layer top plunger 212 includes a lower-layer top body 212a and a lower-layer top tip 212b extending from the lower-layer top body 212a and having a diameter less than a diameter of the lower-layer top body 212a.

The upper-layer top plunger 222 includes an upper-layer top body 222a and an upper-layer top tip 222b extending from the upper-layer top body 222a and having a diameter less than a diameter of the upper-layer top body 222a.

The middle-layer top tip 232 may be provided to have a shape and a size corresponding to the upper-layer and lower-layer top tips 222b and 212b.

Alternatively, the middle-layer top tip 232 may extend upward further than the upper-layer and lower-layer top tips 222b and 212b. Since the middle-layer top tip 232 protrudes, the middle-layer top tip 232 may be more suitable to be connected to a flat surface such as a contact pad. Alternatively, a shape of the middle-layer top tip 232 may be different from shapes of the upper-layer and lower-layer top tips 222b and 212b. A contact point of the middle-layer top tip 232 is disposed at a center thereof and contact points of the upper-layer and lower-layer top tips 222b and 212b may be disposed at both sides thereof.

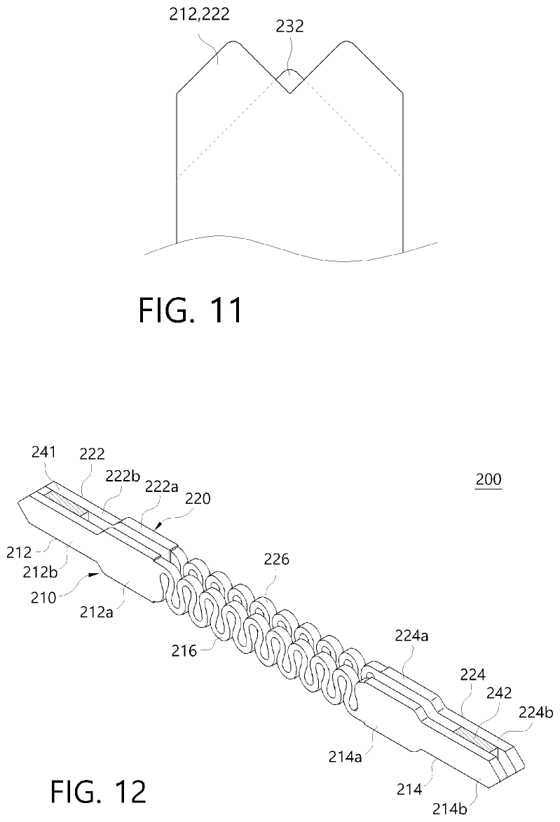

Alternatively, referring to FIG. 11, a middle-layer top tip 232 may be lowered downward further than upper-layer and lower-layer top tips 222b and 212b of upper-layer and lower-layer top plungers 222 and 212. Since the upper-layer and lower-layer top tips 222b and 212b protrude, the upper-layer and lower-layer top tips 222b and 212b may be suitable to be connected to a sphere shape such as a conductive ball.

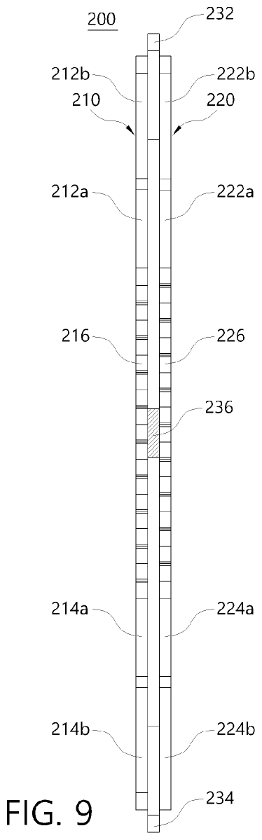

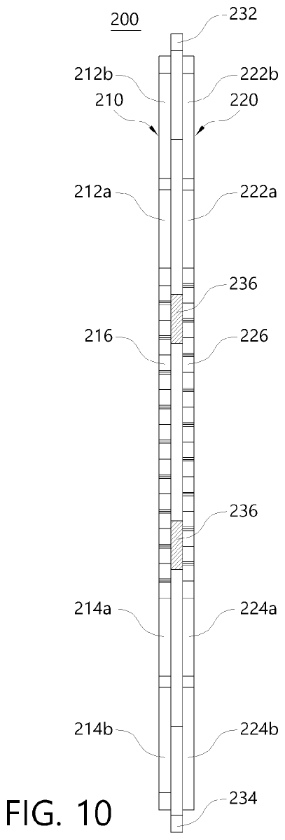

Referring to FIGS. 9 and 10, the three-layer MEMS spring pin 200 further includes one or more middle-layer interposers 236 interposed between the upper-layer wave 226 and the lower-layer wave 216.

The middle-layer interposer 236 may be formed of an electrical conductor or insulator.

The middle-layer interposer 236 may be installed between the upper-layer and lower-layer waves 226 and integrally connected to the upper-layer wave 226 or the lower-layer wave 216 through an adhesive. In this case, the middle-layer interposer 236 is to prevent the upper-layer and lower-layer waves 226 and 216 from being laterally bent, and when the middle-layer interposer 236 is bonded to both of the upper-layer and lower-layer waves 226 and 216, the upper-layer and lower-layer waves 226 and 216 may not independently and elastically operate. Accordingly, the middle-layer interposer 236 may be bonded to one of the upper-layer and lower-layer waves 226 and 216.

That is, the middle-layer interposer 236 is not dependently positioned and is fixed to one of the upper-layer wave 226 or lower-layer wave 216.

Only one middle-layer interposer 236 may be provided as illustrated in FIG. 9, or two middle-layer interposers 236 may be positioned between the upper-layer wave 226 and the lower-layer wave 216 as illustrated in FIG. 10.

In the case in which two middle-layer interposers 236 are provided as illustrated in FIG. 10, the middle-layer interposers 236 may each be fixed to one of the different waves. That is, the middle-layer interposer 236 positioned in an upper portion in the drawing may be fixed to the upper-layer wave 226, and the middle-layer interposer 236 positioned in a lower portion therein may be fixed to the lower-layer wave 216.

Conversely, the middle-layer interposer 236 positioned in the upper portion therein may be fixed to the lower-layer wave 216, and the middle-layer interposer 236 positioned in the lower portion may be fixed to the upper-layer wave 226.

The reason why the middle-layer interposers 236 are each fixed to one of the different waves when being used is to allow the upper-layer wave 226 and the lower-layer wave 216 to have a uniform elastic force.

In the lower-layer wave 216, protrusion portions and groove portions are repeated from one side based on a central line, and in the upper-layer wave 226, protrusion portions and groove portions are repeated from the other side. Accordingly, on the basis of one side based on the central line, the protrusion portions of the lower-layer wave 216 correspond to and intersect with the groove portion of the upper-layer wave 226 and the groove portions of the lower-layer wave 216 correspond to and intersect with the protrusion portions of the upper-layer wave 226.

Similarly, the lower-layer bottom plunger 214 includes a lower-layer bottom body 214a and a lower-layer bottom tip 214b having a diameter less than a diameter of the lower-layer bottom body 214a. The upper-layer bottom plunger 224 includes an upper-layer bottom body 224a and an upper-layer bottom tip 224b having a diameter less than a diameter of the upper-layer bottom body 224a. The middle-layer bottom tip 234 is provided to have a shape and a size corresponding to the upper-layer and lower-layer bottom tips 224b and 214b.

As described above, when the layers are manufactured using a MEMS process, the plungers may be precisely manufactured, and mass production is possible. Particularly, when the plunger is provided through the MEMS process, a contact tip, which comes into contact with a conductive ball or pad, in the plunger may be precisely machined and one of various alloys may be formed on the plunger through a deposition or plating process to improve conductivity.

According to still another embodiment of the present invention, although not illustrated in the drawings, a spring pin may be provided to have a four-or-more-layer.

When plungers are stacked as a four-layer or five-layer, a connection tip may be three-dimensionally designed in a crown shape.

Particularly, since elastic moduli of the layers are formed to be different, a variety of contact characteristics can be implemented.

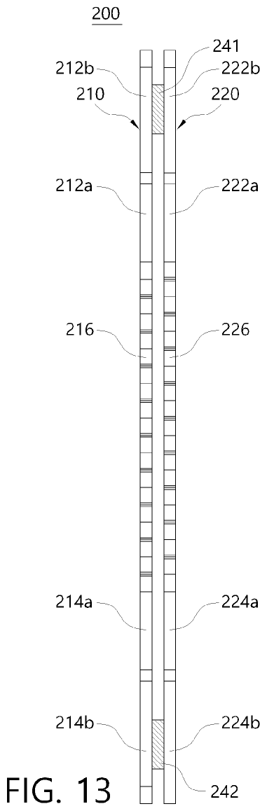

FIG. 12 is a perspective view illustrating a MEMS spring pin according to another embodiment of the present invention, and FIG. 13 is a side view of FIG. 12.

As illustrated in FIGS. 12 and 13, in another embodiment of the present invention, the above-described three-layer MEMS spring pin 200 is used.

That is, a three-layer MEMS spring pin 200 includes a lower-layer spring pin 210 in which a lower-layer wave 216 is disposed between and connected to a lower-layer top plunger 212 and a lower-layer bottom plunger 214, and an upper-layer spring pin 220 in which an upper-layer wave 226 is disposed between and connected to an upper-layer top plunger 222 and an upper-layer bottom plunger 224.

However, a middle-layer top plunger and a middle-layer bottom tip are not used, and the three-layer MEMS spring pin 200 includes a first insulating layer 241 and a second insulating layer 242 respectively positioned between the upper-layer top plunger 222 and the lower-layer top plunger 212 and between the upper-layer bottom plunger 224 and the lower-layer bottom plunger 214.

In the above-described structure, the lower-layer spring pin 210 and the upper-layer spring pin 220 may individually and elastically operate and may be electrically divided by an insulating layer 240.

In addition, the lower-layer top plunger 212 includes a lower-layer top body 212a and a lower-layer top tip 212b extending from the lower-layer top body 212a and having a diameter less than a diameter of the lower-layer top body 212a, and the upper-layer top plunger 222 includes an upper-layer top body 222a and an upper-layer top tip 222b extending from the upper-layer top body 222a and having a diameter less than a diameter of the upper-layer top body 222a.

In FIGS. 12 and 13, the first insulating layer 241 disposed at a top side therein is illustrated as being positioned between the upper-layer top tip 222b and the lower-layer top tip 212b and the second insulating layer 242 positioned at a bottom side therein is illustrated as being positioned between an upper-layer bottom tip 224b and a lower-layer bottom tip 214b.

However, the first insulating layer 241 may be positioned between the upper-layer top body 222a and the lower-layer top body 212a, and similarly, the second insulating layer 242 may be positioned between the upper-layer bottom body 224a and the lower-layer bottom body 214a.

In addition, the first insulating layer 241 may be fully disposed between the lower-layer top plunger 212 and the upper-layer top plunger 222, and similarly, the second insulating layer 242 may be fully disposed between the lower-layer bottom plunger 214 and the upper-layer bottom plunger 224.

An important point in the above-described arrangement is that the first insulating layer 241 should not protrude upward from the upper-layer and lower-layer top tips 222b and 212b, and the second insulating layer 242 should not protrude downward from the upper-layer and lower-layer bottom tips 224b and 214b.

That is, since each of the first insulating layer 241 and the second insulating layer 242 does not protrude further than the top plunger and the bottom plunger, signal transmission and detection are allowed.

As described above, the first insulating layer 241 and the second insulating layer 242 may be added between the lower-layer spring pin 210 and the upper-layer spring pin 220 to individually use the lower-layer spring pin 210 and the upper-layer spring pin 220 as individual pins in the present invention.

Accordingly, individual and different signals may be transmitted to the lower-layer spring pin 210 and the upper-layer spring pin 220.

For example, each of a voltage and a current may be applied to a portion such as a ball of a package required to be tested, and signals having different frequencies may be applied thereto.

As described above, since various different signals may be provided to a test target using practically two pins even in one structure, response to a fine pitch is easy.

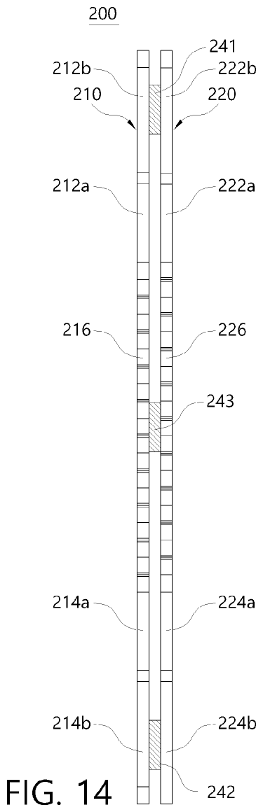

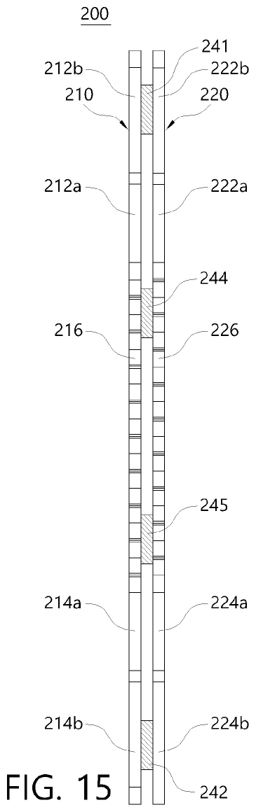

FIGS. 14 and 15 are side views according to another embodiment of the present invention.

In the invention illustrated in FIGS. 14 and 15, an embodiment in which intermediate insulating layers 243, 244, and 245 are disposed between a lower-layer wave 216 of a lower-layer spring pin 210 and an upper-layer wave 226 of an upper-layer spring pin 220 is applied to the structure of the present invention previously described with respect to FIG. 13.

The first insulating layer 241 and the second insulating layer 242 described above are respectively positioned between upper-layer and lower-layer top plungers and between upper-layer and lower-layer bottom plungers and are bonded to both of the upper-layer spring pin 220 and the lower-layer spring pin 210.

In FIG. 14, the intermediate insulating layer 243 positioned between the lower-layer wave 216 and the upper-layer wave 226 is only attached to the lower-layer wave 216 or the upper-layer wave 226.

Accordingly, the lower-layer wave 216 and the upper-layer wave 226 operate individually and elastically due to pressures.

In addition, in FIG. 15, two intermediate insulating layers 244 and 245 are illustrated as being positioned between the lower-layer wave 216 and the upper-layer wave 226. In this case, one of two intermediate insulating layers 244 and 245 is attached to one of the different waves.

That is, the intermediate insulating layer 244 positioned at an upper side in the drawing is attached to the lower-layer wave 216, and the intermediate insulating layer 245 disposed at a lower side therein is attached to the upper-layer wave 226.

Conversely, the intermediate insulating layer 244 may be attached to the upper-layer wave 226, and the intermediate insulating layer 245 may be attached to the lower-layer wave 216.

The reason why each of the intermediate insulating layers 244 and 245 are fixed to one of the different waves when being used is to allow the upper-layer wave 226 and the lower-layer wave 216 to have uniform elastic forces.

As described above, it may be seen that the present invention has a technical spirit in which a one-layer spring pin is easily and elastically deformed, but it is difficult to maintain contact characteristics due to repeated uses, but when the multi-layer spring pin is provided to have the plunger having the multi-layer of which contact characteristics are maintained using the plurality of pins, forms and shapes of various connection tips are provided. Many different modifications may be made by those skilled in the art within a range of the basic technical spirit of the present invention.

### INDUSTRIAL APPLICABILITY

The present invention provides a pin of which a structure includes a plurality of layers configured to individually operate and formed using a fine pattern forming process such as a MEMS process.

1. A multi-layer micro electro mechanical system (MEMS) spring pin comprising:
a lower-layer spring pin in which a lower-layer wave is disposed between and connected to a lower-layer top plunger and a lower-layer bottom plunger;
an upper-layer spring pin in which an upper-layer wave is disposed between and connected to an upper-layer top plunger and an upper-layer bottom plunger;
a middle-layer top tip interposed between the upper-layer top plunger and the lower-layer top plunger; and
a middle-layer bottom tip interposed between the upper-layer bottom plunger and the lower-layer bottom plunger.

2. The multi-layer MEMS spring pin of claim 1, wherein:
the lower-layer top plunger includes a lower-layer top body and a lower-layer top tip; and
the upper-layer top plunger includes an upper-layer top body and an upper-layer top tip.

3. The multi-layer MEMS spring pin of claim 2, wherein the middle-layer top tip extends upward further than the upper-layer and lower-layer top tips.

4. The multi-layer MEMS spring pin of claim 2, wherein the upper-layer and lower-layer top tips extend upward further than the middle-layer top tip.

5. The multi-layer MEMS spring pin of claim 2, further comprising one or more middle-layer interposers interposed between the upper-layer wave and the lower-layer wave.

6. The multi-layer MEMS spring pin of claim 5, wherein the middle-layer interposer is bonded to one of the upper-layer and lower-layer waves.

7. The multi-layer MEMS spring pin of claim 2, wherein:
a protrusion portion of the lower-layer wave corresponds to a groove portion of the upper-layer wave; and
a groove portion of the lower-layer wave corresponds to a protrusion portion of the upper-layer wave.

8. A multi-layer micro electro mechanical system (MEMS) spring pin comprising:
a lower-layer spring pin in which a lower-layer wave is disposed between and connected to a lower-layer top plunger and a lower-layer bottom plunger;
an upper-layer spring pin in which an upper-layer wave is disposed between and connected to an upper-layer top plunger and an upper-layer bottom plunger;
a first insulating layer interposed between the upper-layer top plunger and the lower-layer top plunger; and
a second insulating layer interposed between the upper-layer bottom plunger and the lower-layer bottom plunger.

9. The multi-layer MEMS spring pin of claim 8, wherein:
the first insulating layer does not protrude upward from the upper-layer top plunger and the lower-layer top plunger; and
the second insulating layer does not protrude downward from the upper-layer bottom plunger and the lower-layer bottom plunger.

10. The multi-layer MEMS spring pin of claim 9, further comprising an intermediate insulating layer positioned between the lower-layer wave of the lower-layer spring pin and the upper-layer wave of the upper-layer spring pin.

11. The multi-layer MEMS spring pin of claim 10, wherein:
the intermediate insulating layer is provided as two or more intermediate insulating layers; and
each of the intermediate insulating layers is alternately attached to the lower-layer wave or the upper-layer wave.

12. The multi-layer MEMS spring pin of claim 8, wherein:
the lower-layer top plunger includes a lower-layer top body and a lower-layer top tip; and
the upper-layer top plunger includes an upper-layer top body and an upper-layer top tip.
